(19) United States
(12) Patent Application Publication
(10) Pub. No.: US 2007/0190430 A1
(43) Pub. Date: Aug. 16, 2007

(54) Photo-mask stage

(76) Inventors: Heng-Chung Wu, Tao-Yuan Hsien (TW); Ying-Ming Wu, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/307,500

(22) Filed: Feb. 10, 2006

(51) Int. Cl. G03F 1/00; G03B 27/42

(52) U.S. Cl. 430/5; 355/53

(57) ABSTRACT

A photo-mask stage of an exposure apparatus includes a fixed component to fix a first photo-mask, an exchanging component, which is able to assemble or to disassemble with the fixed component for fixing a second photo-mask.

### BACKGROUND OF THE INVENTION

1. Field of the Invention

The present invention relates to a photo-mask stage of an exposure apparatus, and more particularly, to a photo-mask stage having an exchanging component, which can combine with a fixed component freely.

2. Description of the Prior Art

Lithography is a technology for the photo-mask pattern transfer to a photo-resist and for the substrate to be defined by the special photo-resist pattern. Lithography is applied in manufacturing semiconductors, LCDs, and PDPs for etching masks or ion doping masks.

The scanner exposure apparatus is the most common exposure for the lithography process. In the exposure process, a light source of a scanner exposure apparatus produces exposure light, i-line, KrF laser and ArF laser, etc. When the exposure light passes through the photo-mask and projection lens into the photo-resist surface of the semiconductor wafer or the glass substrate, the photo-mask pattern transfers to the substrate. Then, the substrate stage or the photo-mask stage of the scanner exposure apparatus moves toward the next orientation position, repeats the same exposure process, and the pattern of the photo-mask transfers to the photo-resist of the substrate surface.

In general, the photo-mask uses a panel and see-through quartz as the substrate, a 1000 Å A Cr film covers the photo-mask surface, and then the Cr film is etched by an etching process. The photo-mask surface forms a pattern, which comprises a light pervious section and a light impervious section for the lithography process. In the exposure process, the photo-mask is placed on the photo-mask stage of the scanner exposure apparatus, and then the exposure process is performed.

Owing to the recent increase in panel monitor sizes, the size of the glass substrate is bigger. For the present scanner exposure apparatus, the lens ratio is 1:1 and the photo-mask pattern transfers to the glass substrate. As the photo-mask gets bigger and bigger as the generation changes, the different generation photo-masks are not able to be placed in the same exposure apparatus if the photo-mask stage of the exposure apparatus only can accept one size photo-mask. The apparatus will be wasted and the cost will increase. It is therefore an important issue to design a photo-mask stage for accommodating photo-masks of every generation.

### SUMMARY OF THE INVENTION

The present invention provides a photo-mask stage of an exposure apparatus to solve the above-mentioned problems.

The present invention provides a photo-mask stage of an exposure apparatus. The photo-mask stage includes a fixed component to fix a first photo-mask, an exchanging component, which is able to assemble or to disassemble with the fixed component for fixing a second photo-mask.

The photo-mask stage of the present invention can combine the exchanging component with the fixed component freely, so it be applied to all sizes of photo-masks. The present invention solves the problem of changing the exposure apparatus for different sized photo-masks, and decreases the cost of the equipment.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a plane view diagram of the photo-mask stage of the fixed component according to the present invention.

FIG. 2 is a cross-section diagram of FIG. 1 from I to I′.

FIG. 3 is a plane view diagram of the fixed component of the photo-mask stage combined with the exchanging component according to the present invention.

FIG. 4 is a cross-section diagram of FIG. 3 from II to II′.

FIG. 5 is a schematic diagram of the location of the exposure apparatus according to the present invention.

### DETAILED DESCRIPTION

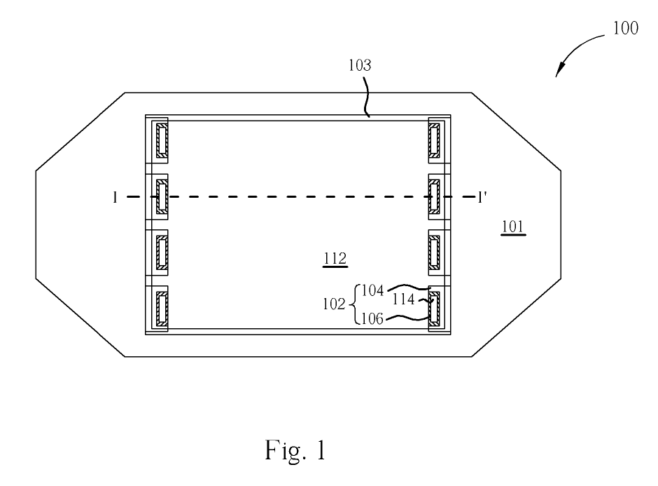

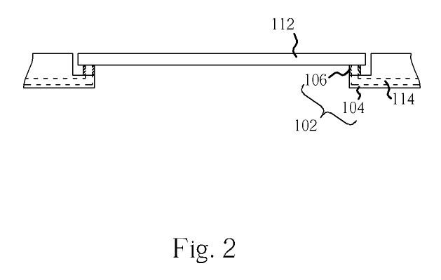

Please refer to FIGS. 1 and 2. FIG. 1 is a plane view diagram of the photo-mask stage of the fixed component according to the present invention. FIG. 2 is a cross-section diagram of FIG. 1 from I to I′. As FIG. 1 shows, a photo-mask stage is a central hollow hollowed board 101, which forms a first part 103 for holding a first photo-mask (ex: first photo-mask 112). A plurality of fixed components 102 are symmetrically disposed on the hollowed board 101 laterals, which are adjacent to the first part 103.

As FIG. 2 shows, each fixed component 102 further comprises an extended part 104, a first gasket 106, and a first air-extracting tube 114, which passes through the extended part 104 and the first gasket 106 of the hollowed board 101. The extended part 104 of the fixed component 102 and the major space 106 on the extended part 104 are used to bear the first photo-mask 112. The first gasket 106 combines with the first air-extracting tube 114 in the hollowed board 101, and the opening of the first air-extracting tube 114 can suck and fix the photo-mask 112. The exposure apparatus uses the first photo-mask 112 in the exposure process, and an extracting apparatus can draw out the air of the first air-extracting tube 114 to from pressure difference, which can make the first photo-mask 112 be held on the first gasket 106 tightly. So, the photo-mask stage 100 can fix the first photo-mask 112. The first photo-mask 112 is placed on the first gasket 106 of the exposure apparatus to focus the lenses for exposure.

The photo-mask stage 100 of the present invention is able to expose the big size photo-mask. When the photo-mask is different size, the present invention can utilize an exchanging component 300 on the fixed component 102 to expose a small size photo-mask. The present invention can accept different size photo-mask by using a different exchanging component 300.

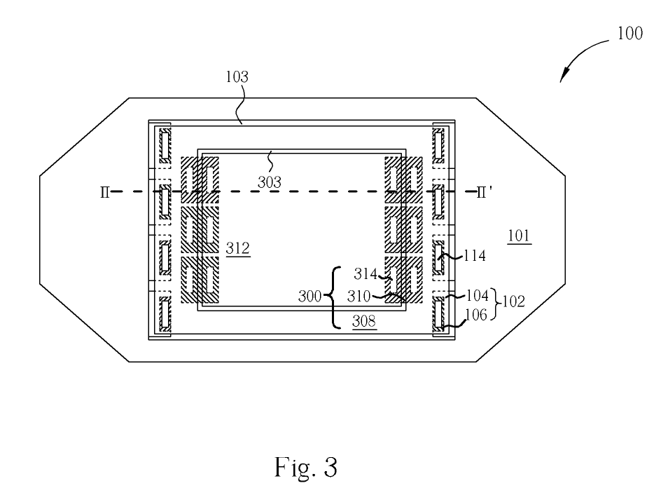

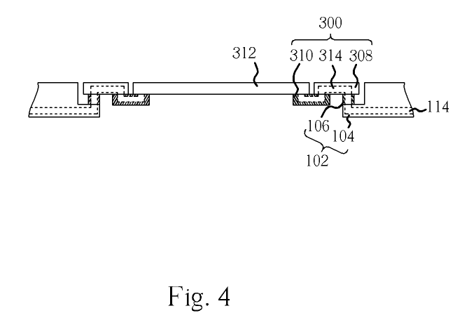

Please refer to FIGS. 3 and 4. FIG. 3 is a plane view diagram of the fixed component of the photo-mask stage combined with the exchanging component according to the present invention. FIG. 4 is a cross-section diagram of FIG. 3 from II to II′. As FIG. 3 shows, the structure and the function of the hollowed board 101 of the photo-mask stage and the fixed component 102 are the same as FIG. 1. The exchanging component 300 comprises a central hollow holder 308, a second gasket 310, and a second air-extracting tube 314, which passes through each second gasket 310 and is disposed in the holder 308. The central hollow of the holder 308 forms a second part 303 to place a second photo-mask 312 second photo-mask 312. When the photo-mask stage 100 is used to carry the second photo-mask 312, because of the product design or dispatch of the products line, the holder 308 of the exchanging component 300 can be combined with the fixed component 102 and be carried the second photo-mask 312. The holder 308 can be locked on the fixed component 102 with a screw or the exchanging component 300 is combined with the fixed component 102 by a slot and the corresponding salient for the stability of the fixed component 102 and the exchanging component 300.

As FIG. 4 shows, when the exchanging component 300 is combined with the fixed component 102, the first air-extracting tube 114 links with the second air-extracting tube 314 and also links with an opening of the second gasket 310 for fixing the second photo-mask 312. So, when the extracting apparatus starts to extract the air of the first air-extracting tube 114, the air of the second air-extracting tube 314 also is extracted, and the pressure difference is formed to suck and fix the second photo-mask 312. As FIG. 4 shows, because the second gasket 310 and the first gasket 106 are adhered to the bottom of the holder 308, the height of the second gasket 310 is the same as the height of the first gasket 106. So, in the exposure process of the photo-mask stage 100 according the present invention, the focus of the first photo-mask 112 is equal with that of the second photo-mask 312. That means the photo-masks have different sizes, and that for exposure at the same height of the exposure apparatus, there is no focus problem. Furthermore, the present invention has also considered that the small photo-mask on the exchanging component 300 might not be corrected by the exposure photo-mask correction system. So, the present invention can set the references of the holder 308, the second gasket 310 and the second photo-mask 312 to correct the location of the photo-mask pattern on the exchanging component 300.

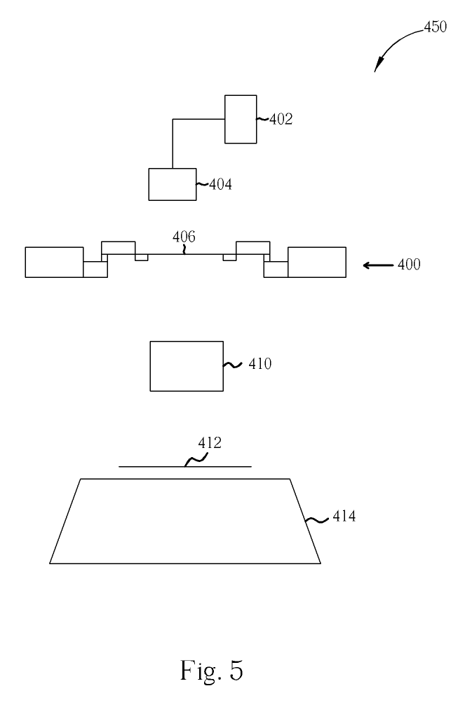

Please refer to FIG. 5. FIG. 5 is a schematic diagram of the location of the exposure apparatus according to the present invention. An exposure apparatus 450 is a scanner exposure apparatus, which has a light source 402, lens 404, a photo-mask stage 400, lens 410, and substrate stage 414. When the exposure process proceeds, the substrate 412 is put on the substrate stage 414, and the photo-mask 406 is put on the photo-mask stage 400. When the light source 402 emits the light, the lens 404 guides the light more uniformly and the pattern of the photo-mask 406 exposures are more complete using the lens 404. The lens 410 has function of contraction or enlargement. In the recent scanner exposure apparatuses, the projection ratio of the lens 410 projecting to the photo-mask pattern into the substrate 412 is 1:1.

In summary, the photo-mask stage 400 of the present invention can be applied for the every kind exposure apparatus 450 of the industry. The photo-mask stage 400 of the present invention can carry different size photo-masks, because the fixed component can carry the big size photo-mask and the fixed component combines with the exchanging component to carry the small size photo-mask.

Comparing with the prior art, the photo-mask stage of the present invention can combine the exchanging component with the fixed component freely, so it can be applied for every size photo-masks. The present invention solves the problem of changing the exposure apparatus for different sized photo-masks, and decreases the equipment cost. In addition, the cost of the photo-mask is more expensive for larger sizes, and the new generation photo-mask is bigger. Using the present invention, only a cheaper small size photo-mask is needed, which has patterns, and the present invention carries the small size photo-mask. The present invention can solve the prior art problem of the single exposure apparatus only being used to carry a single size photo-mask. The cost of equipment decreases. And the present invention decreases the cost of the photo-mask, because the big size can be changed into small size.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A photo-mask stage comprising:
a hollowed board having a first part to place a first photo-mask;
at least a fixed component on the hollowed board to fix the first photo-mask; and
an exchanging component is capable of being assembled and disassembled in the first part, the exchanging component comprising a second part for placing a second photo-mask.

2. The photo-mask stage of claim 1, wherein the photo-mask stage is applied in an exposure apparatus, and a height of the first photo-mask on the fixed component is the same as a height of the second photo-mask on the exchanging component.

3. The photo-mask stage of claim 2, wherein the fixed component comprises:
an extended part for carrying the first photo-mask;
a first spacer on the extended part; and
a first air-extracting tube on the hollowed board formed inside and passing through the extended part and the first gasket.

4. The photo-mask stage of claim 3, wherein the first air-extracting tube contacts with an extracting apparatus, and the first photo-mask is sucked and held on the first gasket by the extracting apparatus.

5. The photo-mask stage of claim 4, wherein the exchanging component comprising:
a holder, comprises the second part;
a plurality of second gaskets formed on the holder to carry the second photo-mask; and
a second air-extracting tube formed in the holder inside and passing through each second gasket.

6. The photo-mask stage of claim 5, wherein the second air-extracting tube contacts with the first air-extracting tube.

7. The photo-mask stage of claim 6, wherein the second air-extracting tube and the first air-extracting tube suck and hold the second photo-mask on the second gasket with the extracting apparatus.

8. The photo-mask stage of claim 5, wherein the holder is fixed on the fixed component with a screw.

9. The photo-mask stage of claim 5, wherein the holder is fixed on the fixed component using a slot and a corresponding salient.

10. The photo-mask stage of claim 2, wherein the exposure apparatus is a scanner exposure apparatus.
